(19) United States
(12) Patent Application Publication
(10) Pub. No.: US 2023/0170439 A1
(43) Pub. Date: Jun. 1, 2023

(54) LIGHT-EMITTING DEVICE

(71) Applicant: TIANJIN SANAN OPTOELECTRONICS CO., LTD., Tianjin (CN)

(72) Inventors: Zhiwei WU, Tianjin (CN); Yanyun WANG, Tianjin (CN); Weiping XIONG, Tianjin (CN); Di GAO, Tianjin (CN); Yu-Ren PENG, Tianjin (CN); Huanshao KUO, Tianjin (CN)

(21) Appl. No.: 17/985,607

(22) Filed: Nov. 11, 2022

(30) Foreign Application Priority Data
Nov. 29, 2021 (CN) 202111436929.5

(51) Int. Cl. H01L 33/38; H01L 33/20

(52) U.S. Cl. CPC H01L 33/38; H01L 33/20

(57) ABSTRACT

A light-emitting device includes a semiconductor structure having a first semiconductor layer, an active layer, and a second semiconductor layer. The second semiconductor layer and the active layer formed on a top surface of the first semiconductor layer exposes a portion of the top surface. A first strip electrode is connected to the exposed top surface. A second strip electrode is connected to the second semiconductor layer. When first and second electrodes are projected on a plane, two parallel lines, that contact two opposite ends of the first electrode and perpendicularly intersect a straight line connecting between two opposite ends of the second electrode, define on the straight line a length, which does not extend beyond a distance between the two opposite ends of the second electrode.

### CROSS-REFERENCE TO RELATED APPLICATION

This application claims priority to Chinese Invention Patent Application No. 202111436929.5, filed on Nov. 29, 2021.

### FIELD

The disclosure relates to a light-emitting device, and more particularly to a semiconductor light-emitting device.

### BACKGROUND

Light-emitting diodes (LEDs) are solid-state semiconductor devices that convert electrical energy into visible light through the combination of holes provided by a p-type semiconductor and electrons provided by an n-type semiconductor. LEDs may emit light of various different colors. Compared to traditional light sources, LEDs have the advantage of longevity, good light efficiency, no ionizing radiation, low power consumption, and low emissions. LEDs have primarily been applied to display screens, indicator lights, and backlighting.

Currently most sub-micron sized flip-chip LED devices have problems such as uneven current spreading, and low anti-electrostatic discharge capabilities that have contributed to low light-emission efficiency and low reliability in conventional flip-chip LED devices. The issues discussed above have limited the application and adoption of flip chip LED devices.

### SUMMARY

Therefore, an object of the disclosure is to provide a light-emitting device that can alleviate at least one of the drawbacks of the prior art.

According to an aspect of the disclosure, the light-emitting device includes a semiconductor structure, a first contact electrode, and a second contact electrode. The semiconductor structure has a first semiconductor layer, an active layer, and a second semiconductor layer that are stacked sequentially. The second semiconductor layer and the active layer are formed on a top surface of the first semiconductor layer and exposing a portion of the top surface that constitutes a mesa structure. The first contact electrode is located on top of the mesa structure and electrically connected to the first semiconductor layer. The second contact electrode is located on top of and electrically connected to the second semiconductor layer. The first contact electrode and the second contact electrode are strip electrodes. When the first and second semiconductor layer, the first contact electrode, and the second contact electrode are projected on an imaginary plane below the semiconductor structure and viewed from above, two parallel first lines, that respectively contact two opposite first ends of the first contact electrode and that perpendicularly intersect a straight second line connecting between two opposite second ends of the second contact electrode, define on the straight second line a length (L2) which does not extend beyond a distance (L1) between the two opposite second ends of the second contact electrode, and a ratio of the length (L2) to the distance (L1) ranges from 0.5 to 1.

According to another aspect of the disclosure, a light-emitting device includes a semiconductor structure having a first semiconductor layer, an active layer, and a second semiconductor layer that are stacked sequentially. The second semiconductor layer and the active layer are formed on a top surface of the first semiconductor layer and expose a portion of the top surface that constitutes a mesa structure. A first contact electrode is located on top of the mesa structure and electrically connected to the first semiconductor layer. A second contact electrode is located on top of and electrically connected to the second semiconductor layer. The second contact electrode includes a second dot-like portion, an initial extending portion, and two auxiliary extending portions, the initial extending portion extends from said second dot-like portion, and the two auxiliary extending portions extend from one end of the initial extending portion distal to the second dot-like portion toward two opposite sides of the semiconductor structure and each having a tip. When the semiconductor structure, the first contact electrode and the second contact electrode are projected on an imaginary plane below the first semiconductor structure and viewed from above, two parallel first lines, that respectively contact two opposite ends of the first contact electrode and that perpendicularly intersect a straight second line connecting between the tips of the auxiliary extending portions, define on the straight second line a length (d2) which does not extend beyond a distance (d1) between the tips of the auxiliary extending portions, and a ratio of the length (d2) to the distance (d1) ranges from 0.3 to 1.

A third aspect of the disclosure is of a display device using the light-emitting device.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a first embodiment of a light-emitting device according to the present disclosure.

FIG. 2 is a schematic cross-sectional view illustrating a variation of the first embodiment.

FIG. 3 is a schematic top view of a second embodiment according to the present disclosure with an insulating layer covering the top of the second embodiment removed to aid better understanding and clearer depiction.

FIGS. 4 and 5 are schematic top views of the second embodiment where first and second contact electrode are curved.

FIG. 6 is a schematic top view showing a variation of the second embodiment where the first contact electrode is straight, while the second contact electrode is curved.

FIGS. 7 and 8 are schematic top views of a third embodiment of the light-emitting device according to the present disclosure with the insulating layer covering the top removed.

FIGS. 9 to 11 are schematic top views of a fourth embodiment of the light-emitting device according to the present disclosure where two auxiliary extension sections of the second electrode are curved and the insulating layer covering the top is removed.

FIGS. 12 to 14 are schematic top views of a fifth embodiment of the light-emitting device according to the present disclosure where the two auxiliary extension sections of the second electrode are straight and the insulating layer covering the top is removed.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

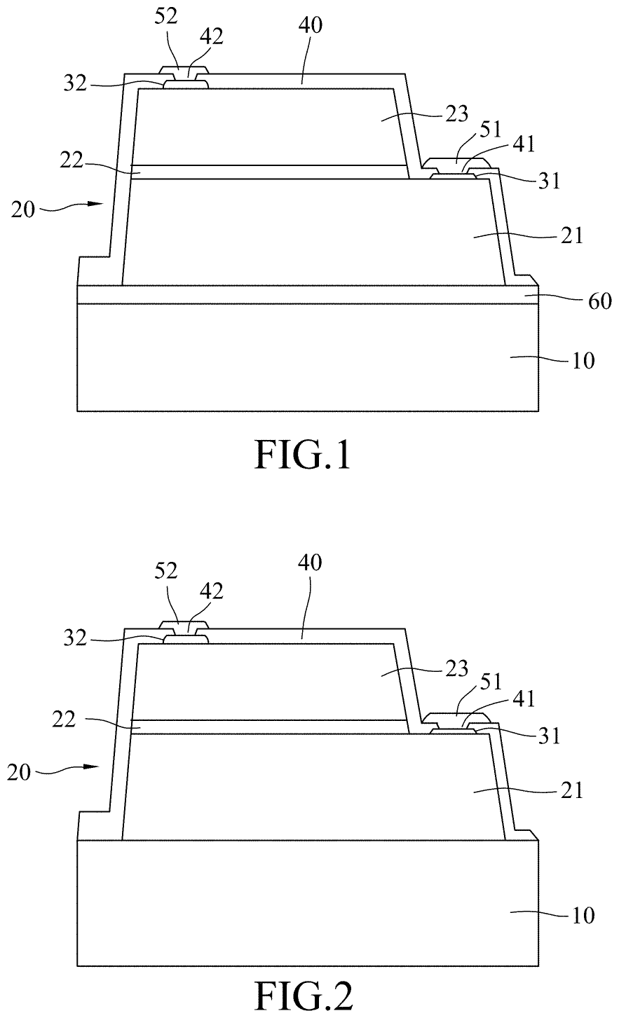

Referring to FIGS. 1 to 3, a first embodiment of the light-emitting device according to the present disclosure is shown. The first embodiment includes a substrate 10, a bonding layer 60, a semiconductor structure 20, a first contact electrode 31, a second contact electrode 32, an insulating layer 40, a first electrode pad 51, and a second electrode pad 52.

The light-emitting device may be a standard-sized LED chip, and may have a horizontal cross-section with an area that is no less than 90,000 μm² and no greater than 2,000,000 μm².

The light-emitting device may be a miniature LED chip or microscale LED with a size that is less than 300 μm when measured lengthwise.

The light-emitting device may be classified as an even smaller sized micro LED chip having a horizontal cross-section with an area that is no more than 10000 μm².

Referring to FIG. 1, the substrate 10 is disposed on the semiconductor structure 20 via the bonding layer 60. When the light-emitting device emits light, the light may pass through the bonding layer 60 and the substrate 10. In this embodiment, the light exit surface of the light-emitting device is a surface of the substrate 10 that is distal to the semiconductor structure 20, and the substrate 10 is a sapphire substrate. The substrate 10 may be a transparent substrate that includes a non-organic material or a III-V compound semiconductor material. The non-organic material may be silicon carbide (SiC), Germanium (Ge), sapphire (Al₂O₃), lithium aluminate (LiAlO₂), zinc oxide (ZnO), glass or quartz. The III-V compound semiconductor material may be indium phosphide (InP), gallium phosphide (GaP), gallium nitride (GaN), or aluminum nitride (AlN). The substrate 10 has enough mechanical strength to support the semiconductor structure 20, and is transparent enough for light to pass through. The substrate 10 has a thickness that is no less than 50 μm. Additionally, in order to facilitate the application of mechanical finishes on the substrate 10 after bonding, the substrate 10 is preferably no greater than 300 μm in thickness.

The bonding layer 60 includes an insulating material or a conducting material. The insulating material may be, including but not limited to, aluminum oxide (Al₂O₃), silicon carbide (SiOₓ), titanium oxide (TiO₂), tantalum oxide (Ta₂O₅), silicon nitride (SiNₓ), or spin on glass (SOG). The conducting material may be including, but not limited to, indium tin oxide (ITO), chromium titanium oxide (CTO), antimony tin oxide (ATO), aluminum zinc oxide (AZO), zinc tin oxide (ZTO), zinc oxide (ZnO), indium zinc oxide (IZO), a diamond like carbon (DLC) thin film, or gallium doped zinc oxide (GZO).

Referring to FIG. 1, the semiconductor structure 20 has a first semiconductor layer 21, an active layer 22, and a second semiconductor layer 23 that are stacked sequentially. The semiconductor structure 20 has a first surface and a second surface opposite to the first surface. In this embodiment, the first surface is the bottom surface of the first semiconductor layer 21, and the second surface is the top surface of the second semiconductor layer 23. The substrate 10 is disposed on the first surface of the semiconductor structure 20 through the bonding layer 60. In some embodiments, the bonding layer 60 is connected to the first semiconductor layer 21 and includes a conducting material (one of the previously described conducting materials). This design facilitates current spreading which increases uniformity of the current distribution in the light-emitting device. In some embodiments, the first surface of the semiconductor structure 20 is a roughened surface, which may decrease the total internal reflection of light emitted from the active layer 22.

The first semiconductor layer 21 and the second semiconductor layer 23 are doped to be different types that either provide electrons or holes depending upon the dopant used. In this case, the first semiconductor layer 21 is a first conductivity type, and the second semiconductor layer 23 is a second conductivity type which is different from the first conductivity type. In some embodiments, the first semiconductor layer 21 is an n-type semiconductor and the second semiconductor layer 23 is a p-type semiconductor. Electrons in the n-type semiconductor recombine with electron holes in the p-type semiconductor under a drive current and light is produced in the active layer 22 in an electroluminescence process.

In this embodiment, the first semiconductor layer 21 includes a III-V compound semiconductor material such as gallium arsenide (GaAs), gallium nitride (GAN), aluminum nitride (AlN), indium nitride (InN), indium gallium nitride (InGaN), aluminum gallium nitride (AlGaN), or indium gallium aluminum nitride (InGaAlN). The first semiconductor layer 21 may include dopants such as magnesium (Mg), and carbon (C); however, this is not a limitation of the disclosure and other dopants may be used. In some variations of the embodiment, the first semiconductor layer 21 may be a single layered structure or a multilayered structure.

In this embodiment, the second semiconductor layer 23 includes a II-VI compound semiconductor material such as zinc selenide (ZnSe) or a III-V compound semiconductor material with one of the elements of the compound belonging to the pnictogen group such as gallium arsenide (GaAs), gallium nitride (GaN), aluminum nitride (AlN), indium nitride (InN), indium gallium nitride (InGaN), aluminum gallium nitride (AlGaN), indium gallium aluminum nitride (InGaAlN). The second semiconductor layer 23 may include a dopant such as silicon (Si) or germanium (Ge); however, this is not a limitation of the disclosure and other dopants may be used. In some variations of the embodiment, the second semiconductor layer 23 may be a single layered structure or a multilayered structure.

In this embodiment, the active layer 22 is a gallium arsenide (GaAs) based semiconductor material. More specifically, when gallium arsenide (GaAs) or aluminum gallium indium phosphide (AlGaInP) is used as a base material of the active layer 22, the light-emitting device may produce red light, orange light or yellow light. On the other hand, when indium gallium aluminum nitride (InGaAlN) is used, blue or green light may be produced. In some variations of the embodiment, the active layer 22 may include an un-doped semiconductor layer or at least one low-doped layer. In some embodiments of the disclosure, the active layer 22 may be a single heterostructure (SH), a double heterostructure (DH), a double-sided double heterostructure (DDH), or a multi quantum well structure (MQW); however, the disclosure is not limited to the above examples.

It should be noted that the light-emitting device is not limited to only having one semiconductor structure 20; in some variations of the embodiment, the light-emitting device may have multiple semiconductor structures 20 on the substrate 10 that may be connected in series, in parallel or both.

The second semiconductor layer 23 and the active layer 22 is formed on a top surface of the first semiconductor layer 21, and removal of a portion of the second semiconductor layer 23 and the active layer 22 exposes a portion of the top surface that constitutes a mesa structure. The mesa structure is constituted to allow the first contact electrode 31 and the second contact electrode 32 to be located on the same side of the semiconductor structure 20, and the portion of the semiconductor layer 23 and the active layer 22 that is removed to constitute the mesa structure is usually around 1 to 2 μm in total thickness.

The first contact electrode 31 is located on top of the mesa structure and is electrically connected to the first semiconductor layer 21 in an ohmic contact. The second contact electrode 32 is located on top of and electrically connected to the second semiconductor layer 23 in an ohmic contact.

In this embodiment, the first contact electrode 31 is a p-type electrode, and the second contact electrode 32 is an n-type electrode. The first contact electrode 31 and the second contact electrode 32 are made of a metal material such as nickel (Ni), gold (Au), chromium (Cr), titanium (Ti), platinum (Pt), palladium (Pd), rhodium (Rh), iridium (Ir), aluminum (Al), tin (Tn), indium (In), tantalum (Ta), copper (Cu), cobalt (Co), iron (Fe), ruthenium (Ru), zirconium (Zr), tungsten (W), and molybdenum (Mo), or any combination or combinations of the above.

In some embodiments, the first and second contact electrodes 31, 32 may each include a contact layer, a reflective layer, a barrier layer, and a top adhesion layer (not shown). In some embodiments of the disclosure, the contact layers are preferably made of chromium (Cr), the reflective layers are preferably made of aluminum (Al), the barrier layers are preferably made of titanium (Ti), nickel (Ni) or platinum (Pt), or an alloy thereof. The top adhesion layer are preferably made of titanium (Ti) which may facilitate adhesion with the insulating layer 40.

The insulating layer 40 covers top surface and side walls of the semiconductor structure 20, and is located above the first contact electrode 31, and the second contact electrode 32.

The insulating layer 40 may provide different effects according to its location. For example, the portion of the insulating layer 40 that is covering the side walls of the semiconductor structure 20 may prevent undesirable electrical connections forming between the first and second semiconductor layers 21, 23.

In this embodiment, the insulating layer 40 includes non-conducting materials. The non-conducting material is preferably an inorganic material or a dielectric material. The inorganic material may include silicone or glass, and the dielectric material may include aluminum oxide (Al₂O₃), silicon nitride (SiNₓ), silicon oxide (SiOₓ), titanium oxide (TiOₓ), or magnesium fluoride (MgFₓ). The insulating layer 40 may also be an electrically insulating material such as silicon dioxide, silicon nitride, titanium oxide, tantalum oxide, niobium oxide, barium titanate, or any combination or combinations of the above. For example, the insulating layer 40 may be assembled from two of the above listed electrically insulating materials formed in alternating stacks to create a distributed Bragg reflector (DBR).

Referring to FIGS. 1 to 3, in this embodiment, the insulating layer 40 has a first through hole 41 and a second through hole 42. The first electrode pad 51 and the second electrode pad 52 are formed on top of the insulating layer 40, and respectively fill in the first through hole 41 and the second through hole 42 to respectively electrically connect with the first contact electrode 31 and the second contact electrode 32.

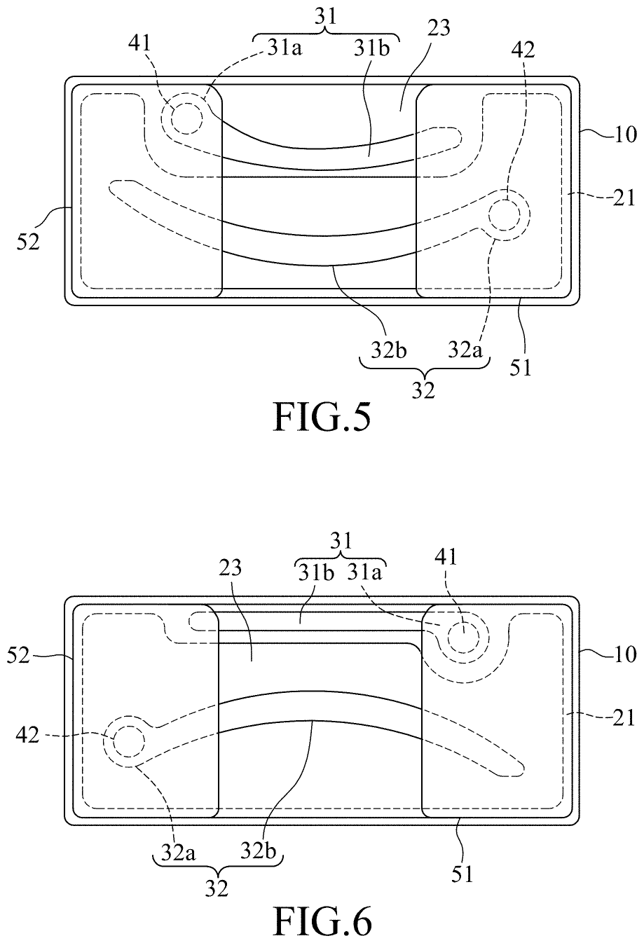

Referring to FIG. 3, in this embodiment, the first electrode pad 51 and the second electrode pad 52 may be rectangular with rounded corners; however this is not a limitation of the disclosure and other shapes are viable. The first electrode pad 51 and the second electrode pad 52 may be formed in the same manufacturing process and made from the same material; and therefore they may have the same structure (such as a layered structure). In other embodiments of the present disclosure, the first electrode pad 51 and the second electrode pad 51 may be a square shaped metallic layer. It is worth noting that in some embodiments the first electrode pad 51 may be a p-type electrode, and the second electrode pad 52 may be an n-type electrode.

It should be noted that the light-emitting device according to the present disclosure may be a flip-chip LED, and the first electrode pad 51 and the second electrode pad 52 may be attached to a printed circuit board via reflow soldering with a tin soldering material to form a light-emitting module such as a display backlight or an RGB display.

When an electrical current is applied to the first electrode pad 51 and the second electrode pad 52, the current will flow toward the first electrode pad 51 from the second electrode pad 52 through the semiconductor structure 20, and be horizontally distributed in the epitaxial structure of the semiconductor structure 20 so that photons are generated through electroluminescence. The active layer 22 may be manufactured with different materials and manufacturing processes to emit light at various different wavelengths and produce various colors.

The light-emitting device of the first embodiment is manufactured by the method described below:

Firstly, the second semiconductor layer 23, the active layer 22 and the first semiconductor layer 21 are sequentially deposited on a growth substrate (not shown in FIG. 1). The deposition process used to deposit these components may be a known deposition growth method such as metal organic chemical vapor deposition (MOCVD), molecular beam epitaxy (MBE), or hydride vapor phase epitaxy (HVPE), and the substrate may be a gallium arsenide substrate.

Next the first surface of the first semiconductor layer 21 is subjected to a roughening process to create a roughened surface on the first semiconductor layer 21. The roughening process may be a type of etching or mechanical planarization; however, it is not limited to these examples and other methods of treating the semiconductor layer may be used to obtain the roughened surface.

After the roughened surface is created on the first semiconductor layer 21, a bonding layer 60 is deposited on the roughened surface and subsequently polished; the semiconductor structure 20 is then bonded to the substrate 10 via the bonding layer 60, and the growth substrate (not shown) is subsequently removed to expose the second semiconductor layer 23.

A portion of the second semiconductor layer 23 and the active layer 22 is removed via photolithography to expose a portion of a top surface of the first semiconductor layer 21 that constitutes a mesa structure. A first contact electrode 31 and a second contact electrode 32 are respectively disposed on the mesa structure and the second semiconductor layer 23. Subsequently, a portion of the semiconductor structure 20 is removed to reveal the bonding layer 60 and form scribe lines. An insulating layer 40 is deposited on the top surface and side walls of the semiconductor structure 20 and the scribe lines.

A first through hole 41 and a second through hole 42 are respectively formed on the areas of the insulating layer 40 that are registered with the first contact electrode 31 and the second contact electrode 32. Subsequently, the first electrode pad 51 is filled into the first through hole 41 to form an electrical connection with the first contact electrode 31, and the second electrode pad 52 is filled in the second through hole 42 to form an electrical connection with the second contact electrode 32.

In this embodiment, the bonding layer 60 is an insulating material such as aluminum oxide (Al₂O₃), titanium dioxide (TiO₂), silicon dioxide (SiO₂), or silicon nitride (SiN), and has a thickness that that ranges from 1 μm to 5 μm.

The scribe lines (not shown) are formed by etching away parts of the semiconductor structure 20, and have a width of no less than 15 μm.

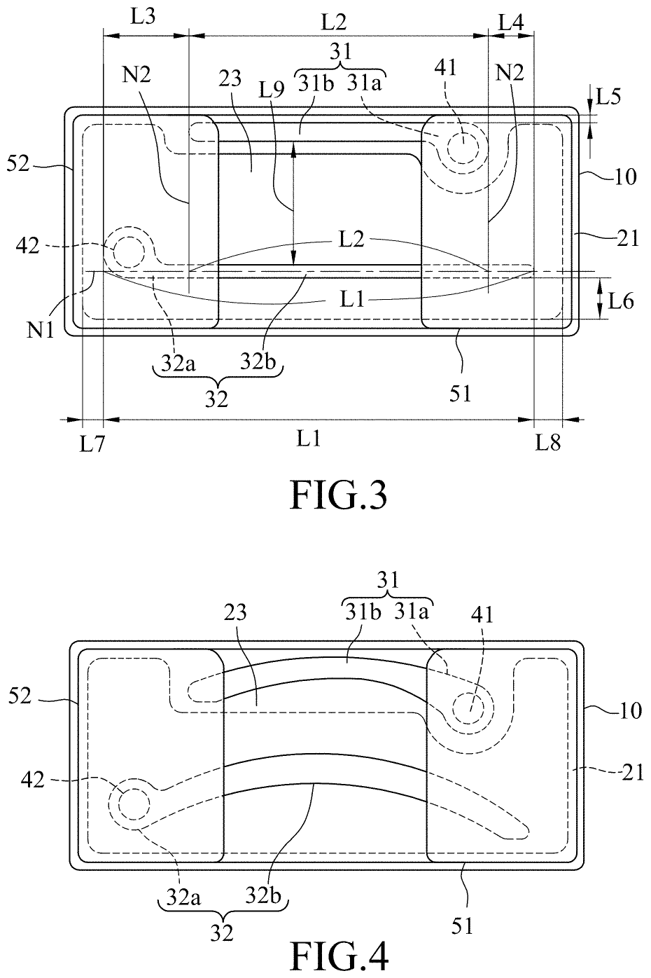

FIG. 2 shows a variation of the first embodiment, with the difference being that the substrate 10 in the variation is a growth substrate. Therefore, the deposition of the bonding layer 60 is unnecessary, and is not present in the variation; the insulating layer 40 covers the surface of the substrate 10 surrounding the semiconductor structure 20 in addition to covering the upper surface and the side walls of the semiconductor structure 20.

The method of manufacturing the variation of the first embodiment is described in detail below:

First, the first semiconductor layer 21, the active layer 22 and the second semiconductor layer 23 are sequentially deposited on a growth substrate (i.e., the substrate 10 shown in FIG. 2) to form the semiconductor structure 20. Next, a portion of the second semiconductor layer 23 and the active layer 22 is removed to expose a top surface of the semiconductor layer 21 that constitutes a mesa structure. The growth substrate 10 used in this example is a sapphire substrate but other suitable materials may be used.

A first contact electrode 31 and a second contact electrode 32 are respectively disposed on the mesa structure and the second semiconductor layer 23.

Next, an insulating layer 40 is formed over the upper surface and the side walls of the semiconductor structure 20, the first contact electrode 31, the second contact electrode 32, and areas of the substrate 10 surrounding the semiconductor structure 20.

A first through hole 41 and a second through hole 42 are formed on areas of the insulating layer 40 that respectively register with the first contact electrode 31 and the second contact electrode 32. The first electrode pad 51 is then filled into the first through hole 41 to be electrically connected to the first contact electrode 31. The second electrode pad 52 is then filled in the second through hole 42 to be electrically connected to the second contact electrode 32.

Referring to FIG. 3, in the first embodiment, the first contact electrode 31 and the second contact electrode 32 are strip electrodes. In this case, the first contact electrode 31 and the second contact electrode 32 are single strip electrodes that do not bifurcate or diverge, and may be shaped as a straight strip, a crooked strip, a bended strip, or a wavy strip. The first contact electrode 31 includes a first dot-like starting section 31a, and a first extension section 31b. The second contact electrode 32 includes a second dot-like starting section 32a, and a second extension section 32b. The first extension section 31b and the second extension section 32b respectively extend from the first dot-like starting section 31a and the second dot-like starting section 32a to form elongated strip shapes.

More specifically, the first dot-like starting section 31a of the first contact electrode 31 is electrically connected to the first electrode pad 51 via the first through hole 41 that passes through the insulating layer 40. The second dot-like starting section 32b of the second contact electrode 32 is electrically connected to the second electrode pad 52 via the second through hole 42 that passes through the insulating layer 40.

A widthwise cross section of at least one of the first extension section 31b and the second extension section 32b has a bottom width that ranges from 5 μm to 15 μm. In this embodiment, both the widthwise cross sections of the first extension section 31b and the second extension section 32b ranges from 5 μm to 15 μm, and the shape of the cross section is trapezoidal. However, in other embodiments, the cross sections may have a different shape. At least one of the first extension section 31b and the second extension section 32b has a tip with a rounded face. When viewed from above the light-emitting diode, at least one of the dot-like starting section 31a and the second dot-like starting section 32a has a circular, horseshoe or oval shape. A widthwise cross section of at least one of the first dot-like starting section 31a and the second dot-like starting section 32a has a bottom width that ranges from 10 μm to 20 μm.

By designing the first contact electrode 31 and the second contact electrode 32 to be strip electrodes, electric current may be facilitated to flow to the first semiconductor layer 21 and the second semiconductor layer 23 and be spread evenly to prevent current crowding effect. Referring to FIG. 3, when the first and second semiconductor layer 21, 23, the first contact electrode 31, and the second contact electrode 32 are projected on an imaginary plane below the semiconductor structure 20 and viewed from above, two parallel first lines, that respectively contact two opposite first ends of the first contact electrode 31 and that perpendicularly intersect a straight second line (N1) connecting between two opposite second ends of the second contact electrode 32, define on the straight second line (N1) a length (L2) which does not extend beyond a distance (L1) between the two opposite second ends of the second contact electrode 32. A ratio of the length (L2) to the distance (L1) ranges from 0.5 to 1. The light-emitting device is designed with these length ratio parameters with the purpose of balancing the current spreading characteristics of the first and second contact electrodes 31, 32. If the first and second contact electrodes 331, 32 are of equal size and shape, the first semiconductor layer 21 has superior current spreading characteristics than the second semiconductor layer 23. Thus, the second semiconductor layer 23 is provided with a comparatively lengthier second contact electrode 32 so that the current spreading characteristics of the second semiconductor layer 23 may be improved to match that of the first semiconductor layer 21.

In this embodiment, the two first lines (N2) intersect the second line (N1) of the second contact electrode 32 at two points that are respectively a distance (L3) and a distance (L4) away from corresponding nearest ones of the two opposite second ends of the second contact electrode 32. The distances (L3) and (L4) are designed to prevent electrostatic discharge (ESD) occurring at the tips of the strip electrodes which may cause failure of the light-emitting device. The distances (L3) and (L4) each ranges from 0 μm to 30 μm, and may be equal to or different from each other.

In this embodiment, the first contact electrode 31 and the second contact electrode 32 are straight and are parallel to each other. A minimum distance (L9) between the first extension section 31b of the first contact electrode 31 and the second extension section 32b of the second contact electrode 32 ranges from 20 μm to 100 μm. By designing the light-emitting device to have a minimum separation distance between the first and second contact electrodes 31, 32 and controlling the distance to be within a specified range, the light emission efficiency and the anti-EDS capabilities of the light-emitting device are improved.

In general, strip electrodes are made lengthier to provide better current spreading and anti-EDS capabilities, and the tips of the strip electrodes are situated so as to avoid being placed too close to a nearest boundary edge of the semiconductor structure 20 (i.e., the nearest boundary edge of the first semiconductor layer 21 or the second semiconductor layer 23). Therefore, some embodiments of the light-emitting device are particularly designed in view of the aforementioned concerns. In the embodiment shown in FIG. 3, when the semiconductor structure 20 and the first and second electrodes 51, 52 are projected on an imaginary plane below the semiconductor structure 20 and viewed from above, a minimum distance (L5) between a boundary edge of the first semiconductor layer 21 and the first contact electrode 31 ranges from 3 μm to 8 μm, and a minimum distance (L6/L7/L8) between a boundary edge of the second semiconductor layer 23 and the second contact electrode 32 ranges from 5 μm to 8 μm.

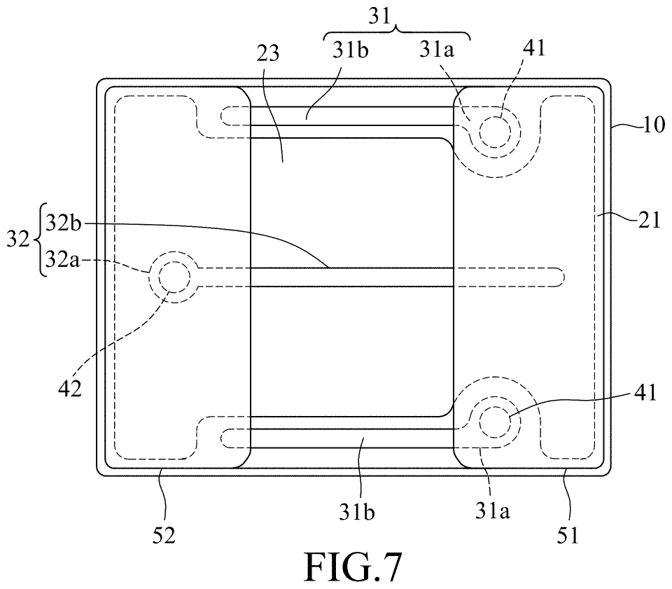

Referring to FIGS. 4, and 5, showing a second embodiment of the light-emitting device according to the present disclosure. The second embodiment is different from the first embodiment in the design of the first contact electrode 31 and the second contact electrode 32. When viewed from above the light-emitting device, the projections of the first contact electrode 31 and the second contact electrode 32 on the imaginary plane are curved. By designing the first and second contact electrodes 31, 32 to be curved, stability of the saturation current may be improved, and the reliability of the light-emitting device may be enhanced. Additionally, curved first and second contact electrodes 31, 32 allow the light-emitting device to have better current spreading, as well as provide the benefits of anti-EDS, stable saturation current, and overall improvement in the reliability of the light-emitting device. In the case where the first and second contact electrodes 31, 32 are curved, the radiuses of curvatures thereof may be varied as the size of the light-emitting device and/or the length of the first and second contact electrodes 31, 32 are varied.

In some embodiments, the first contact electrode 31 and the second contact electrode 32 may have a curvature that is conducive for uniform current spreading. For example, in some embodiments, the curvatures of the first contact electrode 31 and the second contact electrode 32 are constant along their respective lengths. Or, in other embodiments, the curvature of the first contact electrode 31 and the second contact electrode 32 may have curvatures that increase in magnitude along their respective lengths.

In some embodiments, each of the first and second contact electrodes 31, 32 forms an arc of a circle. The curvature of the first contact electrode 31 is concentric with that of the second contact electrode 32 on the imaginary plane where the first and second contact electrode 31, 32 are projected. In this case, an absolute value of a difference between radiuses of curvatures of the first and second contact electrodes is 20 μm to 100 μm.

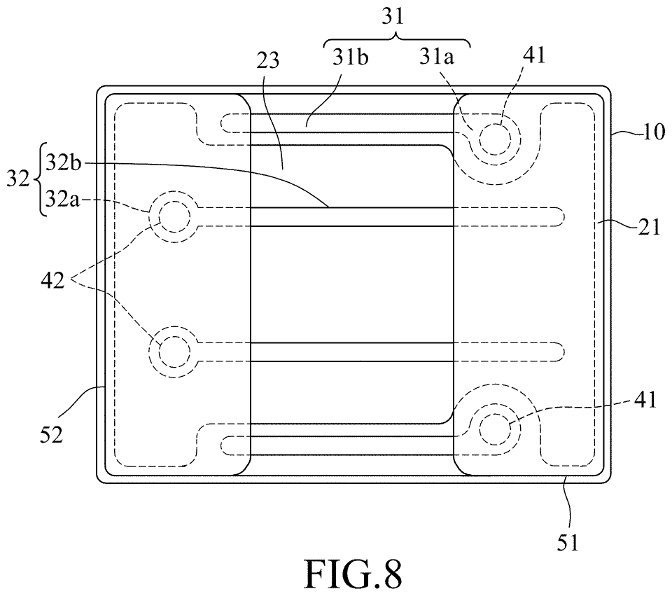

Referring to FIG. 6, in a variation of the second embodiment, the first extension section 31b of the first contact electrode 31 is straight and the second extension section 32b of the second contact electrode 32 is curved.

In some embodiments, at least one of the first and second contact electrodes 31, 32 is designed to have a tip with a curved end face, in order to decrease current crowding occurring at the tip of the strip-shaped first or second electrodes 31, 32. When the first or second electrode 31, 32 is a straight electrode, the curvature of the curved end face of the tip of the straight electrode has a radius equal to the width of the straight electrode.

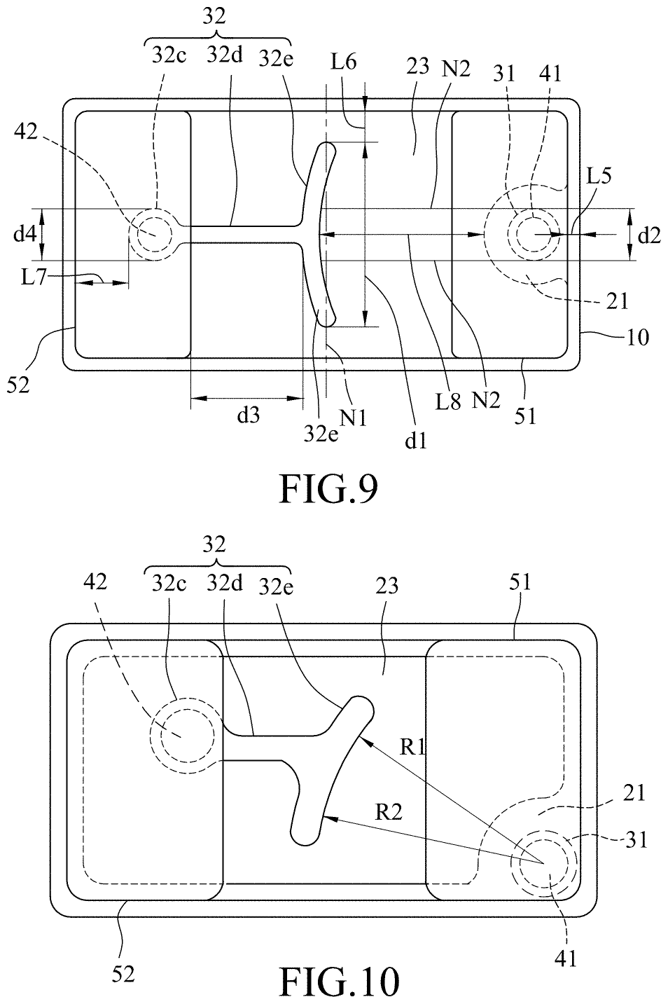

Referring to FIGS. 7 and 8, in a third embodiment of the light-emitting device according to the present disclosure, the arrangement of the first and second contact electrodes 31, 32 is different from that of the first embodiment. Particularly, the number of first and second contact electrodes 31, 32 is varied according to the dimensions of the light-emitting device. In the third embodiment, the first and second contact electrodes 31, 32 are parallel to each other. In FIG. 7, the light-emitting device is shown to include two first contact electrodes 31, one second contact electrode 32, two first through holes 41 and one second through hole 42. In FIG. 8, the light-emitting device is shown to include two first contact electrodes 31 and two second contact electrodes 32, and two first through holes 41, and two second through holes 42 pass through the insulating layer 40.

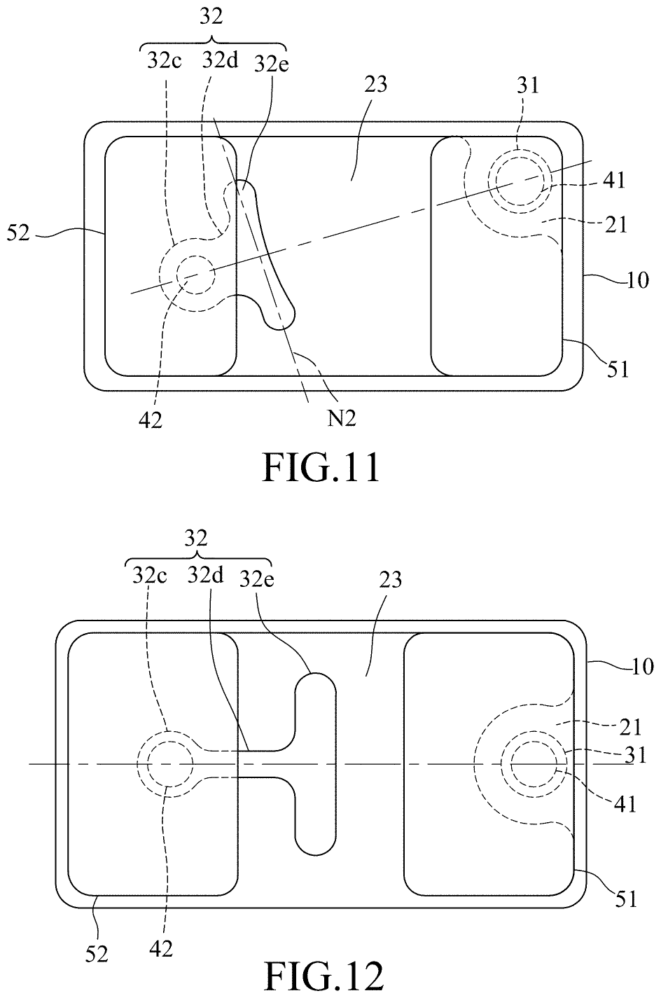

Referring to FIGS. 9 to 11, a fourth embodiment of the light-emitting device has a different design for the first and second contact electrodes 31, 32 in comparison with the first embodiment. In this embodiment, the first contact electrode 31 is a dot-type electrode. The second contact electrode 32 includes a dot-like portion (32c), an initial extending portion (32d), and two auxiliary extending portions (32e). The initial extending portion (32d) is strip-like and extends from the second dot-like portion (32c). The two auxiliary extending portions (32e) extend from one end of the initial extending portion (32d) distal to the second dot-like portion (32c) toward two opposite sides of the semiconductor structure 20 and each has an extremity end. That is to say, the two auxiliary extending portions (32e) have no overlap with the initial extending portion (32d). When viewed from above, the second contact electrode 32 is roughly in a letter-T shape. The two auxiliary extending portions (32e) of the second contact electrode 32 may be straight or curved; however, in this embodiment, the two auxiliary extending portions (32e) are curved.

Referring to FIG. 9, when the semiconductor structure 20, the first contact electrode 31 and the second contact electrode 32 are projected on the imaginary plane below the semiconductor structure 20 and viewed from above, two parallel first lines (N2), that respectively contact two opposite ends of the first contact electrode (31) and that perpendicularly intersect a straight second line change N2 into (N1) connecting between the tips of the auxiliary extending portions (32e), define on the straight second line (N1) a length (d2) which does not extend beyond a distance (d1) between the tips of the auxiliary extending portions (32e). A ratio of the length (d2) to the distance (d1) ranges from 0.3 to 1. This design allows the two auxiliary extending portions (32e) to be situated close to the first contact electrode 31, so that current passing through the second contact electrode 32 may spread out via the two auxiliary extending portions (32e) and the initial extending portion (32d) and prevent current crowding.

In this embodiment, a projection of the second dot-like portion (32c) of the second contact electrode 32 has a length (d4) that is 10 μm to 20 μm, a projection of two opposite ends of the initial extending portion (32d) of the second contact electrode 32 has a distance (d3) that is 0 μm to 60 μm, and a distance between the tips of the two auxiliary extending portions (32e) is greater than 30 μm.

Referring to FIG. 10, in some variations of the fourth embodiment, the two auxiliary extending portions (32e) are curved. The two curved auxiliary extending portions (32e) are respectively the arcs of two circles respectively having radiuses of (R1) and (R2). In some variations, the two circles may be concentric circles. However, in this specific example, the radiuses (R1, R2) of the two circles are equal and the two curved auxiliary extending portions (32e) are arcs of the same circle that is centered on the center of the first contact electrode (31).

Referring to FIG. 11, in this variation of the fourth embodiment, an imaginary line (N3) that passes through the center of the first contact electrode (31) and that is perpendicular to the straight second line (N1) connecting between the tips of the two auxiliary extending portions (32e), will intersect at a mid-point between the two auxiliary extending portions (32e). Electric current may be evenly spread to the two auxiliary extending portions (32e) when this design is adopted.

In some embodiments, a minimum distance between the first contact electrode 31 and the second contact electrode 32 is 20 μm to 100 μm. By virtue of controlling the minimum distance between the first contact electrode 31 and the second contact electrode 32 within the specified parameters, the light-emitting diode may have improved light emitting efficiency and anti-ESD characteristics.

In order to increase the anti-electrostatic discharge characteristics of the light-emitting device, it is preferable for the electrodes (in this case the first and second electrodes 31, 32) not to be too close to the corresponding nearest boundary edge of the semiconductor structure 20 (i.e., the nearest boundary edge of the first and second semiconductor layers 21, 23). In some embodiments, a minimum distance (L5) between the first contact electrode 31 and a boundary edge of the first semiconductor layer 21 ranges from 3 μm to 8 μm, and a minimum distance (L6/L7/L8) between the second contact electrode 32 and a boundary edge of the second semiconductor layer 23 ranges from 5 μm to 10 μm.

In some embodiments, the second dot-like portion (32c), the initial extending portion (32d), and the two auxiliary extending portions (32e) may have widthwise cross sections that are trapezoidal. In this case, the second dot-like portion (32c) has a widthwise cross section with a bottom width of 10 μm to 20 μm, the two initial extending portion (32d) has a widthwise cross section with a bottom width of 5 μm to 10 μm, and the two auxiliary extending portions (32e) has a widthwise cross section with a bottom width of 5 μm to 20 μm.

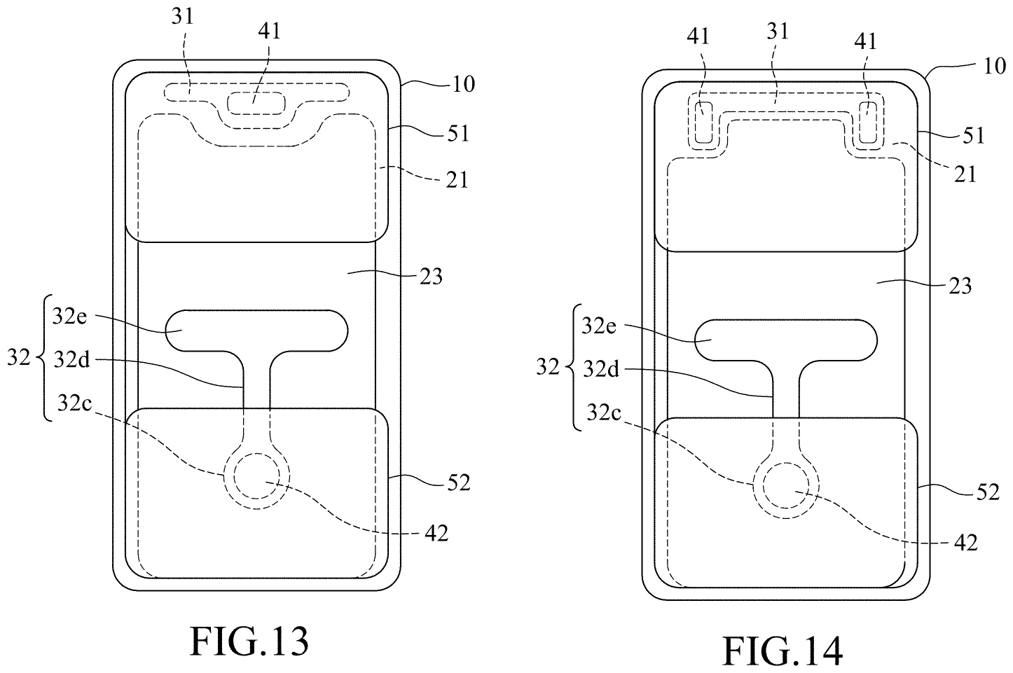

Referring to FIGS. 12 to 14, a fifth embodiment of the light-emitting device according to the present disclosure has a different design for the first contact electrode 31 and the second contact electrode 32 when compared to the first embodiment. In this embodiment, the first contact electrode 31 has one of a dot shape, a strip shape and a curved shape, and the two auxiliary extending portions (32e) are straight extensions. The first contact electrode 31 is a dot shaped electrode as shown in FIG. 12. In FIGS. 13 and 14, the first contact electrode 31 is a straight strip shaped electrode, and the two auxiliary extending portions (32e) are straight extensions. The insulating layer 40 in FIG. 14 has two first through holes 41.

The sixth embodiment of the light-emitting device according to the present disclosure is a display device (not shown) that uses the light-emitting device as described in any of the previous embodiments (embodiments 1 to 5). The display device may be a backlit display device, or an RGB display such as a TV, a mobile phone display, a computer monitor, a display screen, or an outdoor display etc.

An experiment was conducted using three comparative test samples against a light-emitting device according to the first embodiment of the present disclosure. The three comparative test samples (i.e., sample 1, 2 and 3) have a similar structure to the first embodiment, with the only variable being the ratio between the length (L2) to the distance (L1). More specifically, the ratio between the length (L2) that is between the opposite first ends of the first contact electrode 31 and the distance (L1) that is between the opposite second ends of the second contact electrode 32. The three comparative test samples have ratios of 1.1, 1.4 and 1.6 respectively; while the first embodiment has a ratio of 0.69. The first embodiment and the three comparative test samples underwent ESD tests conducted with a Weiming ESD electrostatic discharge simulator under HBM (human-body model) mode, and the test results are shown in Table 1.

TABLE 1

| First | | | |
|---|---|---|---|
| embodiment | Sample 1 | Sample 2 | Sample 3 |
| 2900 V | 2750 V | 2200 V | 2100 V |

The results from Table 1. show that the light-emitting device of the first embodiment of the present disclosure surpasses all the three comparative test samples in anti-ESD capability. Therefore, it can be deduced from the experiment that the larger the length (L2) between the opposite first ends of the first contact electrode (31) compared to the distance (L1) between the opposite second ends of the second contact electrode (32), the worse the anti-ESD capability of the device. This phenomenon becomes especially apparent when the ratio of the (L2) to (L1) is greater than 1. Under such circumstances, the electric field on the opposite second ends of the second contact electrode 32 become much more dense and electric charge becomes crowded around the opposite second ends so that when a large voltage is passed through the light-emitting device, electrostatic discharge will occur at the opposite second ends and cause the light-emitting device to leak electricity.

In summary of the above, the light-emitting device according the disclosure has the following advantages when compared to the conventional light-emitting device: By virtue of stipulating that the two parallel first lines (N2), that respectively contact two opposite first ends of the first contact electrode 31 and that perpendicularly intersect a straight second line (N1) connecting between two opposite second ends of the second contact electrode 32, define on the straight second line (N1) a length (L2), which does not extend beyond a distance (L1) between the two opposite second ends of the second contact electrode 32, and that a ratio of the length (L2) to the distance (L1) ranges from 0.5 to 1, the current spreading characteristics and the anti-ESD capability of the light emitting device is improved. Therefore, the light emitting device according to the present disclosure may have more stable saturation current, and may emit light more evenly, thereby ensuring that the light emitting device has a higher luminous efficacy and superior reliability.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device comprising:
a semiconductor structure having a first semiconductor layer, an active layer, and a second semiconductor layer that are stacked sequentially, said second semiconductor layer and said active layer being formed on a top surface of said first semiconductor layer and exposing a portion of said top surface that constitutes a mesa structure;
a first contact electrode located on top of said mesa structure and electrically connected to said first semiconductor layer; and
a second contact electrode located on top of and electrically connected to said second semiconductor layer;
wherein said first contact electrode and said second contact electrode are strip electrodes;
wherein, when said first and second semiconductor layer, said first contact electrode, and said second contact electrode are projected on an imaginary plane below said semiconductor structure and viewed from above, two parallel first lines, that respectively contact two opposite first ends of said first contact electrode and that perpendicularly intersect a straight second line connecting between two opposite second ends of said second contact electrode, define on the straight second line a length which does not extend beyond a distance between said two opposite second ends of said second contact electrode, and a ratio of the length to the distance ranges from 0.5 to 1.

2. The light-emitting device as claimed in claim 1, wherein said two first lines intersect said straight second line of said second contact electrode at two points that are respectively a distance and a distance away from corresponding nearest ones of said two opposite second ends of said second contact electrode, and said distances each ranges from 0 μm to 30 μm.

3. The light-emitting device as claimed in claim 1, wherein said first contact electrode and said second contact electrode are straight.

4. The light-emitting device as claimed in claim 3, wherein said first contact electrode and said second contact electrode are parallel to each other.

5. The light-emitting device as claimed in claim 4, wherein a minimum distance between said first contact electrode and said second contact electrode ranges from 20 μm to 100 μm.

6. The light-emitting device as claimed in claim 1, wherein:
a minimum distance between a boundary edge of said first semiconductor layer and said first contact electrode ranges from 3 μm to 8 μm; and
a minimum distance between a boundary edge of said second semiconductor layer and said second contact electrode ranges from 5 μm to 10 μm.

7. The light-emitting device as claimed in claim 1, wherein said projections of said first contact electrode and said second contact electrode on said imaginary plane are curved.

8. The light-emitting device as claimed in claim 7, wherein a curvature of said first contact electrode is concentric with that of said second contact electrode on said imaginary plane.

9. The light-emitting device as claimed in claim 8, wherein a difference between radiuses of curvatures of said first and second contact electrodes is 20 μm to 100 μm.

10. The light-emitting device as claimed in claim 1, wherein:
said first contact electrode includes a first dot-like starting section and a first extension section;
said second contact electrode includes a second dot-like starting section and a second extension section;
a widthwise cross section of at least one of said first extension section and said second extension section has a bottom width that ranges from 5 μm to 15 μm; and
a widthwise cross section of at least one of said first dot-like starting section and said second dot-like starting section has a bottom width that ranges from 10 μm to 20 μm.

11. The light-emitting device as claimed in claim 10, wherein at least one of said first extension section and said second extension section has a tip with a curved end face.

12. The light-emitting device as claimed in claim 1, wherein said first contact electrode is straight, and said second contact electrode is curved.

13. The light-emitting device as claimed in claim 1, wherein said light-emitting device is less than 300 μm in length.

14. A light-emitting device comprising:
a semiconductor structure having a first semiconductor layer, an active layer, and a second semiconductor layer that are stacked sequentially, said second semiconductor layer and said active layer being formed on a top surface of said first semiconductor layer and exposing a portion of said top surface that constitutes a mesa structure;
a first contact electrode located on top of said mesa structure and electrically connected to said first semiconductor layer;
a second contact electrode located on top of and electrically connected to said second semiconductor layer;
wherein said second contact electrode includes a second dot-like portion, an initial extending portion, and two auxiliary extending portions, said initial extending portion extending from said second dot-like portion, and said two auxiliary extending portions extending from one end of said initial extending portion distal to said second dot-like portion toward two opposite sides of said semiconductor structure and each having a tip;
Wherein, when said semiconductor structure, said first contact electrode and said second contact electrode are projected on an imaginary plane below said first semiconductor structure and viewed from above, two parallel first lines, that respectively contact two opposite ends of said first contact electrode and that perpendicularly intersect a straight second line connecting between said tips of said auxiliary extending portions, define on the straight second line a length which does not extend beyond a distance between said tips of said auxiliary extending portions, and a ratio of the length to the distance ranges from 0.3 to 1.

15. The light-emitting device as claimed in claim 14, wherein said two auxiliary extending portions of said second contact electrode are straight or curved.

16. The light-emitting device as claimed in claim 14, wherein said first contact electrode has one of a dot shape, a strip shape and a curved shape.

17. The light-emitting device as claimed in claim 14, wherein a minimum distance between said first contact electrode and said second contact electrode is 20 μm to 100 μm.

18. The light-emitting device as claimed in claim 14, wherein, a minimum distance between said first contact electrode and a boundary edge of said first semiconductor layer ranges from 3 μm to 8 μm, and a minimum distance between said second contact electrode and a boundary edge of said second semiconductor layer ranges from 5 μm to 10 μm.

19. The light-emitting device as claimed in claim 14, wherein a projection of said second dot-like portion of said second contact electrode has a length that is 10 μm to 20 μm, a projection of two opposite ends of said initial extending portion of said second contact electrode has a distance that is 0 μm to 60 μm, and a distance between said tips of said two auxiliary extending portions is greater than 30 μm.

20. A display device using the light-emitting device as claimed in claim 1.
